(19) United States
(12) Patent Application Publication
(10) Pub. No.: US 2023/0307326 A1
(43) Pub. Date: Sep. 28, 2023

(54) SEMICONDUCTOR DEVICE, METHOD FOR PRODUCING SEMICONDUCTOR DEVICE, AND POWER CONVERSION APPARATUS

(71) Applicant: Mitsubishi Electric Corporation, Tokyo (JP)

(72) Inventor: Takatoshi YASUI, Tokyo (JP)

(73) Assignee: Mitsubishi Electric Corporation, Tokyo (JP)

(21) Appl. No.: 18/069,804

(22) Filed: Dec. 21, 2022

(30) Foreign Application Priority Data
Mar. 3, 2022 (JP) 2022-032575

(51) Int. Cl. H01L 23/495; H01L 23/00; H01L 25/07

(52) U.S. Cl. CPC H01L 23/49513; H01L 23/49524; H01L 23/49562; H01L 24/32; H01L 24/48; H01L 25/072; H01L 2224/32225; H01L 2224/32245; H01L 2224/48151

(57) ABSTRACT

A semiconductor device includes an insulating substrate, a semiconductor element joined onto the insulating substrate with a first joining material interposed therebetween, a plurality of support wires that are provided between the semiconductor element and an electrode plate provided above the semiconductor element in contact with the semiconductor element and the electrode plate, and a second joining material that is provided on the semiconductor element and joins the semiconductor element and the electrode plate.

### BACKGROUND OF THE INVENTION

### Field of the Invention

The present disclosure relates to a semiconductor device, a method for producing the semiconductor device, and a power conversion apparatus.

### Description of the Background Art

In recent years, in a vehicle field, an industrial machine field, or a consumer equipment field, a semiconductor device capable of operating at a high voltage and a large current is required. In addition, a semiconductor device that operates at a high voltage and a large current is also required to have a high heat radiation property since a mounted semiconductor element becomes high in temperature due to its own heat generation. Therefore, a semiconductor device in which an electrode plate is joined onto a semiconductor element has been proposed. One example is the semiconductor device of Japanese Patent Application Laid-Open No. 2016-129254.

However, the semiconductor device of Japanese Patent Application Laid-Open No. 2016-129254 is not configured in consideration of suppression of inclination of the electrode plate on the semiconductor element, and has a problem that the electrode plate may be inclined.

### SUMMARY

An object of the present disclosure is to obtain a semiconductor device capable of suppressing inclination of an electrode plate above a semiconductor element.

A semiconductor device according to the present disclosure includes an insulating substrate, a semiconductor element, an electrode plate, a plurality of support wires, and a second joining material.

The semiconductor element is joined onto the insulating substrate with a first joining material interposed therebetween.

The electrode plate is provided above the semiconductor element.

The plurality of support wires are provided between the semiconductor element and an electrode plate in contact with the semiconductor element and the electrode plate.

The second joining material is provided on the semiconductor element and joins the semiconductor element and the electrode plate.

Since the electrode plate on the semiconductor element is supported by the plurality of support wires, inclination of the electrode plate can be suppressed.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view illustrating a semiconductor device according to a first preferred embodiment;

FIG. 2 is a cross-sectional view of the semiconductor device according to the first preferred embodiment taken along line A-A in FIG. 1;

FIGS. 3 and 4 illustrate a modification of the semiconductor device according to the first preferred embodiment;

FIG. 5 is an electric circuit diagram illustrating a configuration of the semiconductor device according to the first preferred embodiment;

FIG. 6 is a cross-sectional view illustrating a configuration in which the semiconductor device according to the first preferred embodiment is attached to a heat sink 20;

FIG. 7 is a partially enlarged view of a region surrounded by the broken line 80 in the semiconductor device according to the first preferred embodiment;

FIGS. 8, 9, 10A to 10D, and 11 illustrate a modification of the semiconductor device according to the first preferred embodiment;

FIG. 12 is a schematic view of a case where an electrode plate 7 is inclined;

FIG. 13 is a plan view illustrating a semiconductor device according to a modification of the first preferred embodiment;

FIG. 14 is a cross-sectional view illustrating the semiconductor device according to the modification of the first preferred embodiment;

FIG. 15 is a cross-sectional view illustrating a configuration in which the semiconductor device according to the modification of the first preferred embodiment is attached to a heat sink 20;

FIG. 16 is a cross-sectional view illustrating a semiconductor device according to a second preferred embodiment;

FIG. 17 illustrates a modification of the semiconductor device according to the second preferred embodiment;

FIG. 18 is a cross-sectional view illustrating a semiconductor device according to a third preferred embodiment;

FIG. 19 illustrates a modification of the semiconductor device according to the third preferred embodiment;

FIG. 20 is a block diagram illustrating a configuration of a power conversion system according to a fourth preferred embodiment; and

FIG. 21 is a flowchart illustrating a method for producing the semiconductor device according to the first preferred embodiment.

### DESCRIPTION OF THE PREFERRED EMBODIMENTS

Hereinafter, preferred embodiments will be described with reference to the drawings. Since the drawings are schematically illustrated, the interrelationships in size and position may be changed. In the following description, identical or corresponding constituent elements are given identical reference signs, and repeated description thereof may be omitted.

In addition, in the following description, terms meaning specific positions and directions such as “upper”, “lower”, “front”, “back”, “left”, “right” and “side” may be used, but these terms are used for convenience to facilitate understanding of the contents of the embodiments, and do not limit positions and directions during actual implementation.

### First Preferred Embodiment

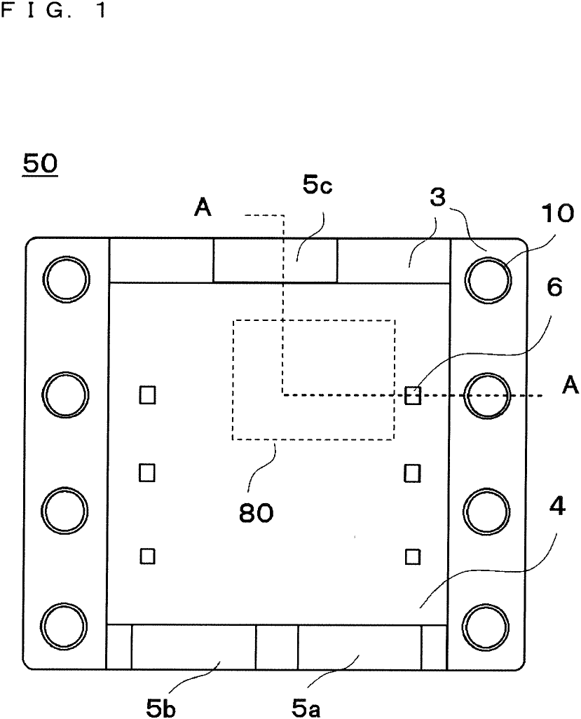

A semiconductor device 50 according to the first preferred embodiment will be described below. FIG. 1 is a plan view illustrating the semiconductor device 50 according to the first preferred embodiment.

As illustrated in FIG. 1, the semiconductor device 50 has eight metal bushes 10, which are cylindrical metal, on a surface of a case 3 having a quadrangular shape in plan view at left and right end portions of the case 3. Each of the metal bushes 10 has a through hole through which a bolt or the like can be inserted, and for example, the semiconductor device 50 is fixed to a heat sink or the like with a bolt. Note that when the semiconductor device 50 is fixed to a heat sink or the like, the semiconductor device 50 may be fastened with a screw screwed through the metal bush 10 and a washer. A material of the metal bushes 10 may be any metal such as copper or iron, but is preferably a metal having good workability and low material cost such as brass or aluminum. Although the case 3 is insert-molded by embedding the metal bushes 10, the case 3 may be outsert-molded by fixing the metal bushes 10 to through holes passing through the case 3 by press-fitting.

The metal bushes 10 are provided in one row on each of the left and right sides of the case 3, and a row of the metal bushes 10 provided on the left side of the case 3 and a row of the metal bushes 10 provided on the right side of the case 3 are arranged in parallel. The plurality of metal bushes 10 are arranged at equal intervals in each row. Note that the metal bushes 10 need not necessarily be provided, but in a case where the metal bushes 10 are provided, it is only necessary that two or more metal bushes 10 be provided, and the number of metal bushes 10 is not limited to eight. It is also possible to employ a configuration in which only one metal bush 10 is provided at each of four corners of the case 3. In addition, the metal bushes 10 need not necessarily be arranged in parallel and at equal intervals.

An electrode 5a, an electrode 5b, and an electrode 5c are electrodes 5 for electrically connecting the semiconductor device 50 and an external apparatus, and are exposed from the surface of the case 3. The electrode 5a is a P terminal of the semiconductor device 50, the electrode 5b is an N terminal of the semiconductor device 50, and DC power is input from a power supply apparatus or the like, which is an external apparatus, to the semiconductor device 50 via the P terminal and the N terminal. The electrode 5c is an output terminal of the semiconductor device 50, and DC power input from the electrode 5a and the electrode 5b is converted by the semiconductor device 50 and is output to a load apparatus, which is an external apparatus, via the electrode 5c. The electrode 5a and the electrode 5b are each provided on a side parallel to and opposed to a side on which the electrode 5c is provided on the surface of the case 3, and are preferably provided on a side orthogonal to the side on which the row of the metal bushes 10 is provided on the surface of the case 3. Note that the electrode 5a and the electrode 5b need not necessarily be provided on a side parallel to and opposed to the side on which the electrode 5c is provided on the surface of the case 3 and need not necessarily be provided on a side orthogonal to the side on which the row of the metal bushes 10 is provided. The electrode 5a and the electrode 5b may be provided on the side where the row of the metal bushes 10 is provided. Although the case where three electrodes 5, specifically, the electrodes 5a, 5b, and 5c, which are a P terminal, an N terminal, and an output terminal, respectively, are provided is described, the number of electrodes 5 may be two in a case where the N terminal also serves as an output terminal. The number of electrodes 5 is not limited, as long as two or more electrodes 5 are provided.

A signal terminal 6 is a terminal used for input and output of an electric signal between the semiconductor device 50 and an external apparatus. The signal terminal 6 is exposed from a sealing material 4. Note that the signal terminal 6 may be provided on the surface of the case 3. In addition, the number of signal terminals 6 may be one or more, and is not limited to six. As illustrated in FIG. 1, the signal terminals 6 are provided between the rows of the metal bushes 10 provided on the left and right sides of the case 3, and the signal terminals 6 are arranged in parallel to the row of the metal bushes 10 provided on the left side of the case 3 and the row of the metal bushes 10 provided on the right side of the case 3. Although the signal terminals 6 are arranged in parallel to each other, the signal terminals 6 need not necessarily be arranged in parallel. Although the signal terminals 6 are arranged at equal intervals, the signal terminals 6 need not necessarily be arranged at equal intervals.

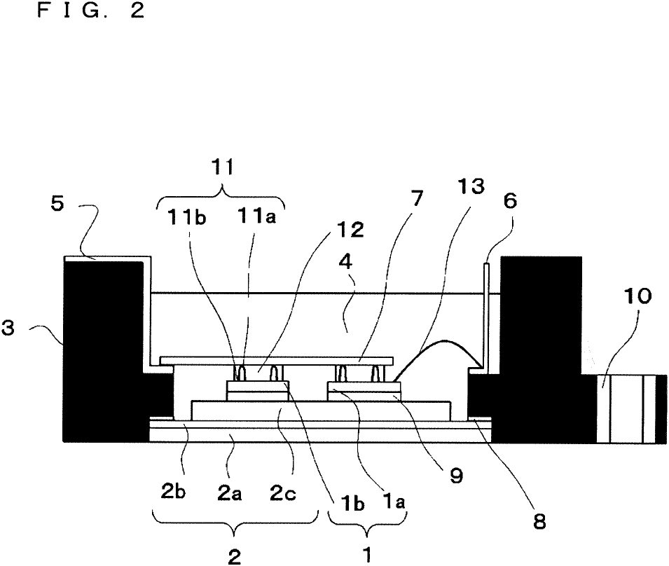

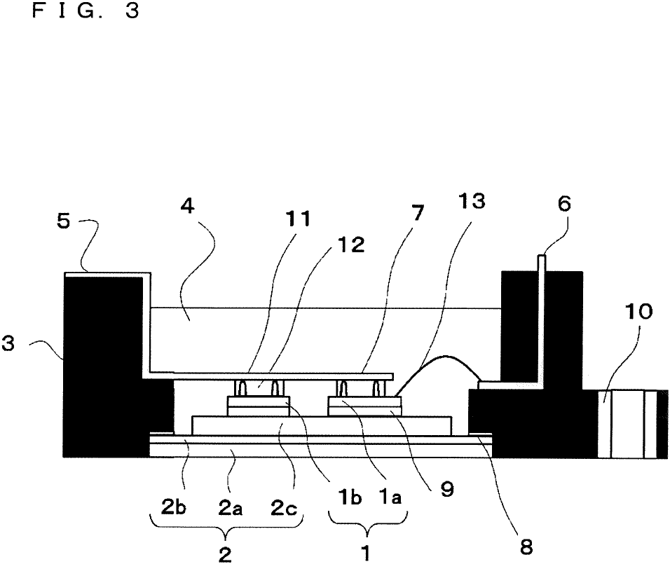

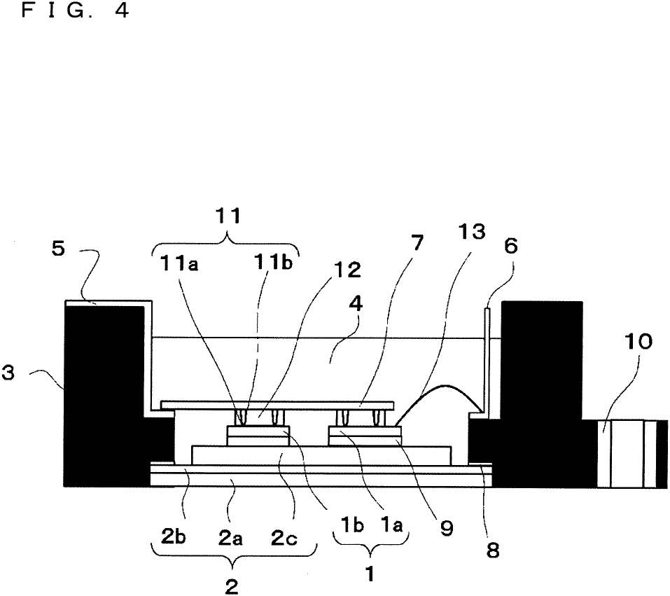

FIG. 2 is a cross-sectional view illustrating the semiconductor device 50 according to the first preferred embodiment of the present disclosure, FIG. 2 is a cross-sectional view of the semiconductor device 50 taken along broken line A-A illustrated in FIG. 1, and FIGS. 3 and 4 are cross-sectional views of a modification of the semiconductor device 50. As illustrated in FIG. 2, the semiconductor device 50 is provided with a semiconductor element 1 (1a, 1b), an insulating substrate 2, the case 3, the sealing material 4, the electrodes 5, the signal terminals 6, an electrode plate 7, the metal bushes 10, and a support wire 11.

The semiconductor element 1 (1a, 1b) only needs to be a switching element or a diode. For example, an insulated gate bipolar transistor (IGBT), a metal-oxidesemiconductor field-effect transistor (MOSFET), a reverse conducting IGBT (RC-IGBT), or the like may be used, and a diode or the like may be used as a reflux element. The number of semiconductor elements 1 is not limited to one, and may be two or more.

The insulating substrate 2 includes a metal plate 2a, an insulating member 2b, and a circuit pattern 2c. The semiconductor element 1 is joined to the circuit pattern 2c with solder that is first joining material 9 interposed therebetween. The insulating member 2b is provided on the metal plate 2a, and the insulating member 2b and the metal plate 2a are, for example, joined by a brazing material or a sintered material. The circuit pattern 2c is provided on the insulating member 2b, and the insulating member 2b and the circuit pattern 2c are, for example, joined by a brazing material or a sintered material. The metal plate 2a and the circuit pattern 2c may be made of any metal, and are, for example, made of copper. The metal plate 2a is a heat radiation plate that radiates heat generated in the semiconductor element 1, and the circuit pattern 2c forms an electric circuit of the semiconductor device 50. The insulating member 2b only needs to ensure electrical insulation with the semiconductor element 1, and may be formed of, for example, an inorganic ceramic material or a resin material. In the above description, the metal plate 2a, the insulating member 2b, and the circuit pattern 2c of the insulating substrate 2 are integrated with each other. However, the metal plate 2a and the insulating member 2b may be provided as individual components instead of being integrally included in the insulating substrate 2.

The electrode plate 7 is made of copper (Cu). The electrode plate 7 is disposed on the semiconductor element 1 with the second joining material 12 and the support wire 11 interposed therebetween, and a front surface electrode (e.g., an emitter electrode in the case of an IGBT, and an anode electrode in the case of a diode) of the semiconductor element 1 and a lower surface of the electrode plate 7 are joined by the second joining material 12. Note that the second joining material 12 only needs to be electrically conductive, and may be, for example, a brazing material such as a silver paste or solder. The lower surface of the electrode plate 7 is disposed so as to face not only the front surface electrode of the semiconductor element 1 but also a surface of the insulating substrate 2. That is, the semiconductor element 1, the insulating substrate 2, and the electrode plate 7 are arranged so as to be parallel to each other.

As illustrated in FIG. 1, the electrodes 5 are the electrode 5a, which is a P terminal of the semiconductor device 50, the electrode 5b, which is an N terminal of the semiconductor device 50, and the electrode 5c, which is an output terminal of the semiconductor device 50. One ends of the electrodes 5 are electrically connected to the semiconductor element 1 with the electrode plate 7, the circuit pattern 2c, the conductive wire 13, or the like, and the other ends of the electrodes 5 are used for electrical connection with an external apparatus for the semiconductor device 50.Although not illustrated, the electrode 5 and the electrode plate 7 may be joined with a joining material such as solder interposed therebetween or may be joined by solid phase bonding using ultrasonic vibration or the like.

One ends of the signal terminals 6 are electrically connected with a control electrode on the surface of the semiconductor element 1, the circuit pattern 2c, the conductive wire 13, or the like interposed therebetween, and the other ends of the signal terminals 6 are used for input and output of an electric signal to and from an external apparatus for the semiconductor device 50. Note that the circuit pattern 2c may be interposed or need not be interposed. The electrodes 5 and the signal terminals 6 only need to be electrically conductive, and may be, for example, copper. Note that as for the control electrode, not only a gate electrode for controlling ON/OFF of the semiconductor element 1, but also, for example, a current sense electrode or a Kelvin emitter electrode may be provided. The current sense electrode is an electrode for sensing a current flowing through a cell region of the semiconductor device 50, and the Kelvin emitter electrode is an electrode for measuring a temperature of the semiconductor device 50. Accordingly, a plurality of signal terminals 6 may be provided corresponding to the control electrodes.

Although the electrodes 5 and the signal terminals 6 have been described in FIG. 2, as a modification, the electrodes 5 may be provided integrally with the electrode plate 7, and an insert case structure may be employed in which the signal terminals 6 are integrated with the case 3. For example, FIG. 3 illustrates a modification of the semiconductor device 50 in which the electrodes 5 and the electrode plate 7 in FIG. 2 are integrally formed, and the signal terminals 6 and the case 3 are integrated. In FIG. 3, one end of the electrode plate 7 is electrically connected to the semiconductor element 1, and the other end of the electrode plate 7 is used for electrical connection with an external apparatus for the semiconductor device 50. Parts of the signal terminals 6 are embedded in the case 3, one ends of the signal terminals 6 are electrically connected to the semiconductor element 1, and the other ends of the signal terminals 6 are used for input and output of an electric signal to and from an external apparatus for the semiconductor device 50.

The semiconductor element 1 and the insulating substrate 2 are surrounded by the case 3. The case 3 is fixed to an end portion of the insulating member 2b with an adhesive 8 interposed therebetween, and the adhesive 8 is provided on four sides of the insulating member 2b corresponding to the shape of the case 3 having a quadrangular shape in plan view in order to fix the quadrangular case 3.Note that it is only necessary that the adhesive 8 be provided so that the sealing material 4 does not leak from between the insulating substrate 2 and the case 3 when the case 3 is filled with the sealing material 4 as a result of connecting the insulating substrate 2 and the case 3. Although the insulating member 2b and the case 3 are fixed with the adhesive 8, the metal plate 2a or the circuit pattern 2c may be fixed to the case 3 with the adhesive 8. The case 3 is formed of an insulator such as poly phenylene sulfide resin (PPS).

The semiconductor element 1, the insulating substrate 2, the electrodes 5, the signal terminals 6, the conductive wire 13, and others surrounded by the case 3 are covered with the sealing material 4. End portions of the electrodes 5 and the signal terminals 6 are exposed from the sealing material 4 in order to be connected to an external apparatus for the semiconductor device 50. Although an outsert case structure in which the case 3, the electrodes 5, and the signal terminals 6 are fixed to the case 3 by press fitting or screw fastening has been described in FIG. 2, an insert case structure may be employed in which the electrodes 5 and the signal terminals 6 are embedded in the case 3 and the electrodes 5, the signal terminals 6, and the case 3 are integrated. For example, FIG. 3 illustrates the insert case structure in which the signal terminals 6 and the case 3 are integrated as described above. A back surface of the insulating substrate 2 is exposed from the sealing material 4 so as to be cooled by a heat sink or the like. The sealing material 4 is not particularly limited as long as the sealing material 4 is an insulating material, and may be, for example, a silicone gel or an epoxy-based resin or may be, for example, a direct potting resin or the like that is sealed with a liquid epoxy resin. In a case of a direct potting resin, transfer molding, or the like, a lid, the case 3, or the like need not be provided above the sealing material 4.

The support wire 11 is provided on the semiconductor element 1 after the semiconductor element 1 is joined onto the insulating substrate 2 with the first joining material 9 interposed therebetween. A plurality of support wires 11 are provided between the front surface of the semiconductor element 1 and the lower surface of the electrode plate 7, and the plurality of support wires 11 come into contact with the electrode plate 7 and the semiconductor element 1 so that a distance between the front surface of the semiconductor element 1 and the lower surface of the electrode plate 7 becomes constant, and thereby inclination of the electrode plate 7 can be suppressed. That is, the support wires 11 are provided so that the front surface of the semiconductor element 1 and the lower surface of the electrode plate 7 are parallel to each other. After the electrode plate 7 and the semiconductor element 1 are held by the support wires 11 so that the distance between the electrode plate 7 and the semiconductor element 1 becomes constant, the semiconductor element 1 and the electrode plate 7 are joined with the second joining material 12 interposed therebetween. After the semiconductor element 1 and the electrode plate 7 are joined by the second joining material 12, the semiconductor element 1 and the electrode plate 7 are sealed by the sealing material 4 as described above. In a case where the electrode plate 7 is inclined at a time of providing the sealing material 4, there is a concern that an end portion of the electrode plate 7 is exposed from the sealing material 4. However, an end portion of the electrode plate 7 can be prevented from being exposed from the sealing material 4 by supporting the electrode plate 7 with the support wires 11.

Each of the support wires 11 has, on both end portions thereof, a distal end portion 11b that is solid-phase joined by wire bonding. In addition, each of the support wires 11 has a vertex portion 11a where the height of the wire is the highest among portions of the support wire 11. Note that the vertex portion 11a may be provided as a vertex point of a loop shape formed by the support wire 11 or may be formed as a line or a surface having the same height, and the vertex portion 11a need just be formed at a position higher than the distal end portion 11b even if the loop shape of the support wire 11 is squashed.

Each of the distal end portions 11b is a start point or an end point at which solid-phase joining is performed by wire bonding, and the distal end portions 11b are provided apart from each other by 0.5 mm or more. The distance between the distal end portions 11b is set 0.5 mm or more in order to prevent tool interference during wire bonding. In addition, the distance is set in order to prevent the distal end portions 11b from interfering with each other due to a squashing width since the distal end portions 11b are squashed when wire bonding is performed. As illustrated in FIG. 2, the distal end portion 11b is joined to the semiconductor element 1, and the vertex portion 11a comes into contact with the electrode plate 7, and thereby the electrode plate 7 is supported so that inclination of the electrode plate 7 is suppressed. Note that the distal end portion 11b may be joined to the electrode plate 7, and the vertex portion 11a may come into contact with the semiconductor element 1. For example, FIG. 4 illustrates, as a modification of FIG. 2, a modification of the semiconductor device 50 in which the distal end portion 11b is joined to the electrode plate 7 and the vertex portion 11a comes into contact with the semiconductor element 1. As illustrated in FIG. 4, the distal end portion 11b is joined to the electrode plate 7, and the vertex portion 11a comes into contact with the semiconductor element 1, and thereby the electrode plate 7 is supported so that inclination of the electrode plate 7 is suppressed.

A stress buffer material may be provided in a region around the support wires 11 between the front surface of the semiconductor element 1 and the lower surface of the electrode plate 7. The stress buffer material may be any material that can buffer stress, and is, for example, polyimide. The region around the support wires 11 is a region surrounding the entire support wires 11 or at least the distal end portions 11b. Assuming that a region where the distal end portions 11b of the support wires 11 are joined to the front surface of the semiconductor element 1 is a distal end portion joining region, the stress buffer material is provided around the distal end portion joining region on the front surface of the semiconductor element 1. That is, the stress buffer material is provided on the front surface of the semiconductor element 1 excluding the distal end portion joining region. By providing the stress buffer material around the support wires 11, stress on the support wires 11 can be suppressed, and therefore wire joining life is improved. In addition, stress from a wire bonding tool onto the semiconductor element 1 can be lessened when the support wires 11 are solid-phase joined to the front surface of the semiconductor element 1 by wire bonding.

Although a diameter of the support wires 11 is preferably 30 µm or more and 500 µm or less in consideration of rigidity and cushioning properties during supporting, the diameter of the support wires 11 is more preferably 100 µm or more and 500 µm or less since the number of support wires 11 needs to be increased as the diameter of the support wires 11 becomes smaller. Furthermore, the semiconductor element 1 includes an active region through which a main current flows, and a termination region for maintaining a withstand voltage of the semiconductor element 1 around the active region. The support wires 11 are preferably provided on the active region on the front surface of the semiconductor element 1, but if the number of the support wires 11 is too large, the support wires are also actively provided on an outer peripheral side of the semiconductor element 1 that is on the termination region side outside the active region. In a case where the support wires 11 are provided on the outer peripheral side of the semiconductor element 1 which is the termination region side of the semiconductor element 1, there is a concern that a creepage distance from a collector electrode is shortened and a short circuit between a collector and an emitter occurs, and therefore it is preferable to appropriately keep the number of support wires 11 small by setting the diameter of the support wires 11 to 100 µm or more. Note that the stress buffer material provided on the front surface of the semiconductor element 1 described above may be provided on either the active region or the termination region or may be provided across the active region and the termination region.

A material of the support wires 11 may be any electrically conductive metal, and may be, for example, aluminum, copper, silver, gold, or the like. Since the main current of the semiconductor device 50 flows from the emitter electrode on the front surface of the semiconductor element 1 to the electrode plate 7 side, the electrically conductive support wires 11 allow heat generated from the semiconductor element 1 to be radiated above the semiconductor element 1, thereby improving heat radiation from an upper side of the semiconductor element 1. By using support wires 11 having a higher thermal conductivity than second joining material 12, heat radiation from the upper side of the semiconductor element 1 is further improved. The support wires 11 may be partially or entirely embedded in the second joining material 12 but need not necessarily be embedded in the second joining material 12. In a case where the support wires 11 are embedded in the second joining material 12, thermal stress to a portion where the semiconductor element 1 and the support wires 11 are joined can be suppressed by using, as the support wires 11, a member having a linear expansion coefficient close to that of the second joining material 12, and therefore heat radiation from the upper side of the semiconductor element 1 can be further improved. Furthermore, in a case where the support wires 11 are embedded in the second joining material 12 when the sealing material 4 is provided, the support wires 11 can be prevented from falling down due to a pressure from the sealing material 4.

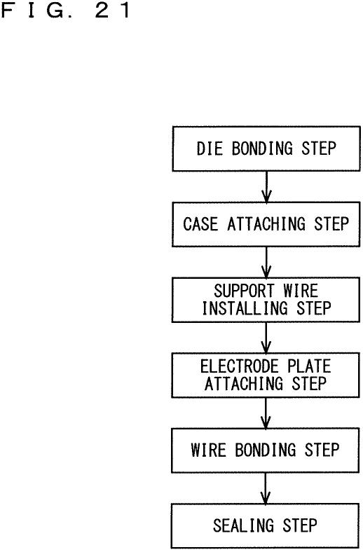

A method for producing the semiconductor device 50 will be described below with reference to the flowchart of FIG. 21. The method for producing the semiconductor device 50 includes a die bonding step, a case attaching step, a support wire installing step, an electrode plate attaching step, a wire bonding step, and a sealing step.

In the die bonding step, the first joining material 9 is disposed on the insulating substrate 2, and the semiconductor element 1 is joined thereon. Note that the semiconductor element 1 and the insulating substrate 2 may be joined by using a plate solder as the first joining material 9 and melting the plate solder by performing heat treatment by reflow.

Next, in the case attaching step, the case 3 and the insulating substrate 2 are bonded with the adhesive 8. By filling a gap between the case 3 and the insulating substrate 2 with the adhesive 8, it is possible to prevent leakage of the sealing material 4 injected in a later step.

Next, in the support wire installing step, the plurality of support wires 11 are provided on the front surface of the semiconductor element 1 or the electrode plate 7 so that the semiconductor element 1 and the electrode plate 7 are arranged in parallel. The support wires 11 are solid-phase joined to the front surface of the semiconductor element 1 by wire bonding or is solid-phase joined to the lower surface of the electrode plate 7 by wire bonding. As a result, the vertex portions 11a of the support wires 11 having a loop shape come into contact with the lower surface of the electrode plate 7 or the front surface of the semiconductor element 1, and the distance between the semiconductor element 1 and the electrode plate 7 is kept constant, and the semiconductor element 1 and the electrode plate 7 become parallel. Note that the support wire installing step may be performed before the case attaching step.

Next, in the electrode plate attaching step, the second joining material 12 is disposed on the semiconductor element 1, and the electrode plate 7 is placed on the support wires 11 while bringing the support wires 11 and the electrode plate 7 into contact with each other. Since the plurality of support wires 11 support the electrode plate 7, inclination of the electrode plate 7 can be suppressed. In a case where the second joining material 12 is a plate solder, the plate solder is provided on the semiconductor element 1 within a region surrounded by the support wires 11, and the plate solder is melted by performing heat treatment by reflow while keeping the distance between the semiconductor element 1 and the electrode plate 7 constant by the support wires 11, and thereby the semiconductor element 1 and the electrode plate 7 are joined. Note that the semiconductor element 1 and the electrode plate 7 may be joined by providing a through hole in the electrode plate 7, pouring the second joining material 12 onto the semiconductor element 1 through the through hole after the electrode plate 7 is arranged on the support wires 11.

Next, in the wire bonding step, the control electrode and the signal terminals 6 on the front surface of the semiconductor element 1 are wire-bonded so as to form a desired circuit by the conductive wire 13. Note that the support wire installing step may be omitted by providing the support wires 11 during the wire bonding step using the conductive wire 13. In a case where the support wires 11 are provided during the wire bonding step, the electrode plate attaching step is performed after the wire bonding step.

Next, in the sealing step, after the semiconductor element 1 and the electrode plate 7 are joined by the second joining material 12, the sealing material 4 is injected into a region surrounded by the case 3 and the insulating substrate 2 to perform sealing, and thereby the semiconductor device 50 is completed. In a case where the electrode plate 7 is inclined at a time of providing the sealing material 4, there is a concern that an end portion of the electrode plate 7 is exposed from the sealing material 4. However, an end portion of the electrode plate 7 can be prevented from being exposed from the sealing material 4 since inclination of the electrode plate 7 is suppressed by supporting the electrode plate 7 with the support wires 11.

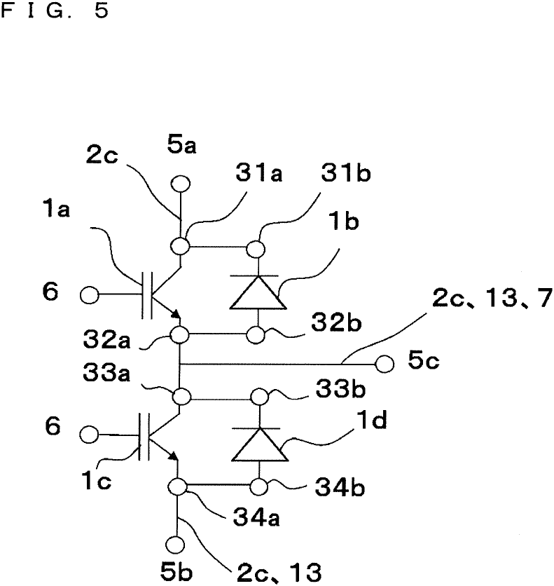

FIG. 5 is an electric circuit diagram illustrating a configuration of the semiconductor device 50 according to the first preferred embodiment of the present disclosure. As illustrated in FIG. 5, in a case where the semiconductor element 1 is an IGBT, the semiconductor device 50 constitutes a 2-in-1 module half bridge circuit that is a case where two sets of circuits in which a diode is located on the circuit pattern 2c and the IGBT and the diode are connected in parallel are prepared and connected in series.

The electrode 5a is electrically connected to a collector electrode 31a, which is a back surface electrode of the semiconductor element 1a, by the circuit pattern 2c. Furthermore, the collector electrode 31a of the semiconductor element 1a and a cathode electrode 31b of a diode 1b are electrically connected by the circuit pattern 2c, and an emitter electrode 32a, which is a front surface electrode of the semiconductor element 1a, and an anode electrode 32b, which is a front surface electrode of the diode 1b, are electrically connected by the electrode plate 7, and thereby a parallel circuit of the semiconductor element 1a and the diode 1b is formed. The electrode 5b is electrically connected to an emitter electrode 34a, which is a front surface electrode of the semiconductor element 1c, by the circuit pattern 2c or the conductive wire 13. Furthermore, the emitter electrode 34a of the semiconductor element 1c and an anode electrode 34b, which is a front surface electrode of the diode 1d, are electrically connected by the conductive wire 13 or the circuit pattern 2c, and a collector electrode 33a, which is a back surface electrode of the semiconductor element 1c, and a cathode electrode 33b, which is a back surface electrode of the diode 1d, are electrically connected by the conductive wire 13 or the circuit pattern 2c, and thereby a parallel circuit of the semiconductor element 1c and the diode 1d is formed. The electrode 5c is electrically connected to the emitter electrode 32a of the semiconductor element 1a and the collector electrode 33a of the semiconductor element 1c by the electrode plate 7, the circuit pattern 2c, the conductive wire 13, or the like. Note that when members are electrically connected to each other, the electrical connection may be performed via the circuit pattern 2c, the electrode plate 7, the conductive wire 13, or the like.

Two sets of parallel circuits are formed, and a 2-in-1 module half bridge circuit is formed by connecting an upper arm that is one of the parallel circuits and a lower arm that is the other one of the parallel circuits in series. Needless to say, a circuit configuration different from the above circuit configuration may be employed, and for example, a 1-in-1 module parallel circuit or a 6-in-1 module three-phase inverter circuit may be formed. The electrode 5c may omitted depending on the circuit configuration.

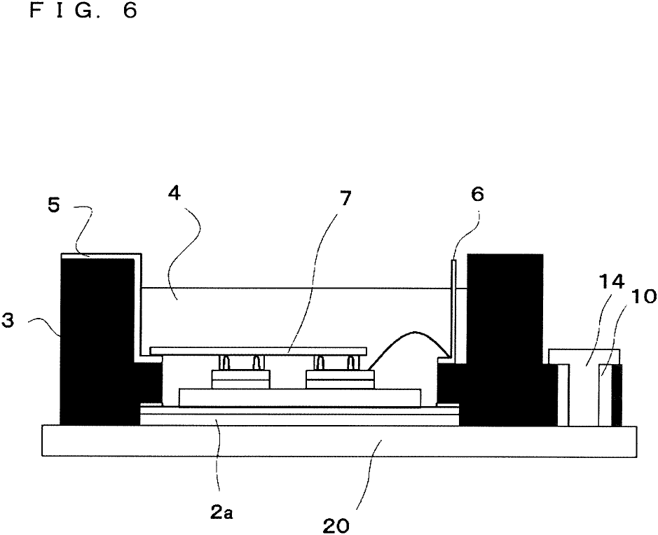

FIG. 6 is a cross-sectional view illustrating a configuration in which the semiconductor device 50 according to the present disclosure is attached to a heat sink 20. The configuration other than the heat sink 20 in FIG. 6 is identical to that in FIG. 2, and FIG. 6 is a cross-sectional view illustrating a configuration in which the semiconductor device 50 and the heat sink 20 are fastened by a screw 14.

The heat sink 20 is fixed to the semiconductor device 50 with a screw 14 screwed through the metal bush 10. The metal bush 10 has a through hole, and the through hole has a cylindrical shape and has a constant inner diameter in a direction from the front surface toward the back surface of the insulating substrate 2, so that the screw 14 can be inserted through the through hole. Since the semiconductor element 1 generates heat during use of the semiconductor device 50, the heat is radiated from the back surface of the metal plate 2a through the heat sink 20. Therefore, the semiconductor device 50 and the heat sink 20 are fastened with the screw 14 screwed through the metal bush 10 so that the metal plate 2a and the heat sink 20 can be kept in contact with each other. In the plan view of FIG. 1, the inner diameter and the outer diameter of each of the metal bushes 10 are concentric circles within a range of a manufacturing error.

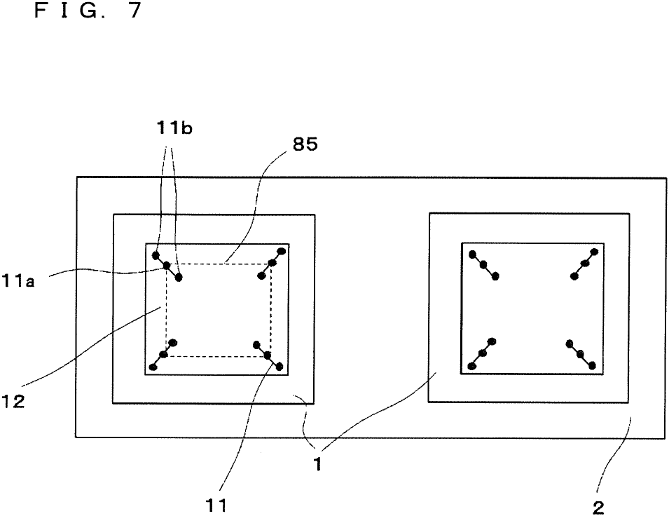

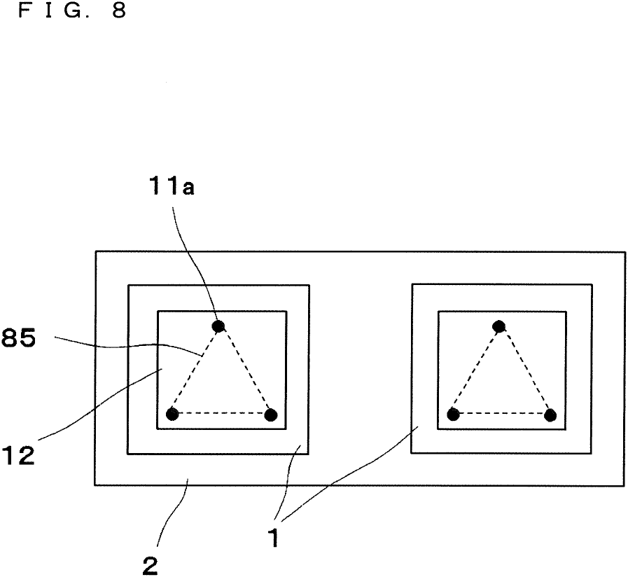

FIG. 7 is a partially enlarged view of a region surrounded by the broken line 80 in the semiconductor device 50 illustrated in FIG. 1. FIGS. 8, 9, 10A to 10D, and 11 are diagrams illustrating modifications of FIG. 7. In the following description, the sealing material 4, the electrode plate 7, and others are omitted for convenience of description.

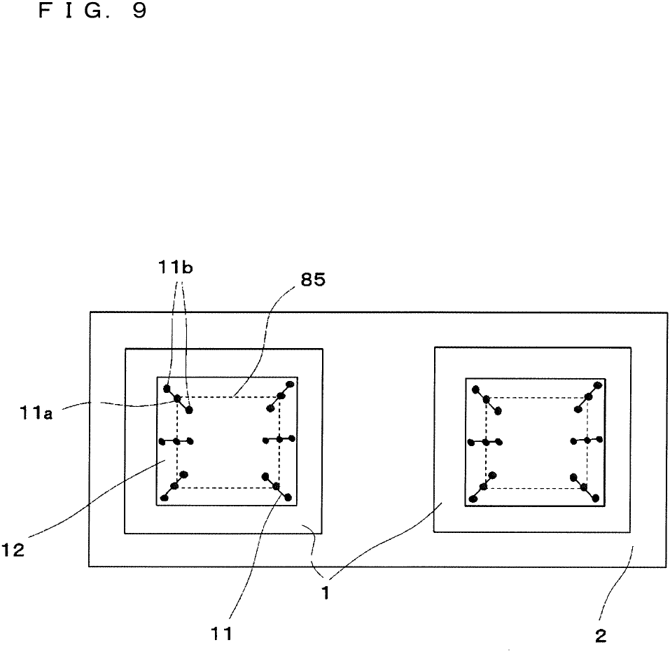

Each of the support wires 11 has the vertex portion 11a and the distal end portion 11b. The vertex portion 11a is a portion of the support wire 11 that includes a point having a highest loop height, and the distal end portion 11b is a portion including a joining point of the support wire 11. Four support wires 11 are arranged on the front surface of each semiconductor element 1, and the support wires 11 are arranged so that a quadrangular shape is formed when the vertex portions 11a of the support wires 11 are connected by the virtual line 85 in plan view. Although two support wires 11 may be provided on the front surface of each semiconductor element 1, it is preferable that three or more support wires are provided. In a case where two support wires 11 are provided on the front surface of each semiconductor element 1, the virtual line 85 connecting the vertex portions 11a is a line segment between two points. However, in a case where three support wires 11 are provided, the support wires 11 are disposed so that a triangular shape is formed when the vertex portions 11a of the support wires 11 are connected by the virtual line 85 in plan view, for example, as illustrated in FIG. 8, and since a plane is formed by three points, the electrode plate 7 can be supported more stably. In FIG. 8, only the vertex portions 11a are illustrated for convenience of description. As the number of support wires 11 increases, the electrode plate 7 can be more stably supported, and therefore inclination of the electrode plate 7 can be suppressed. Therefore, it is only necessary that the support wires 11 are disposed so that a polygonal shape is formed corresponding to the number of support wires 11 when the vertex portions 11a of the support wires 11 are connected by the virtual line 85. Since a polygonal shape closer to a regular polygon shape is more stable, the support wires 11 may be disposed so that a regular polygon shape is formed when the vertex portions 11a are connected by the virtual line 85. In a case where the support wires 11 are, for example, disposed so that a quadrangular shape is formed when the vertex portions 11a of the support wires 11 are connected by the virtual line 85 in plan view, four or more support wires 11 may be disposed as illustrated in FIG. 9 to further suppress inclination of the electrode plate 7, as long as the vertex portions 11a thereof are located on the virtual line 85 forming the quadrangular shape. The same applies to other polygonal shapes.

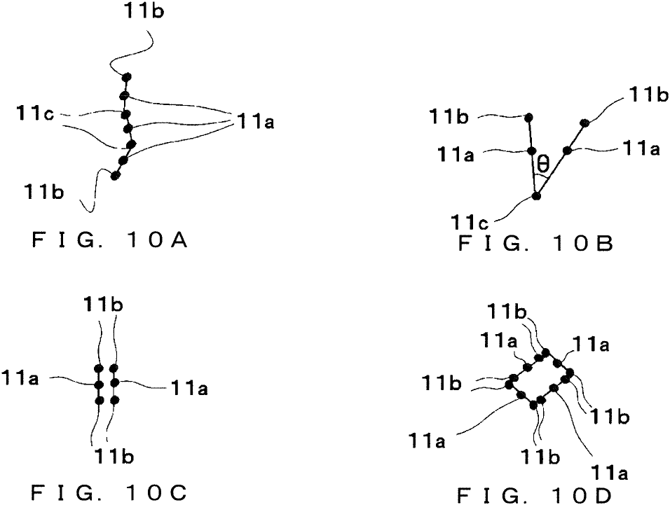

FIGS. 10A to 10D illustrate modifications of the support wires 11. As illustrated in FIG. 10A, a plurality of joint portions 11c are also provided between the distal end portions 11b that are both ends of one support wire 11. That is, by continuously providing the support wires 11, a plurality of vertex portions 11a may be provided in one support wire 11 instead of providing one vertex portion 11a in one support wire 11, and the support wire 11 may have a plurality of loop shapes. As illustrated in FIG. 10B, the support wires 11 may be continuously provided at an angle θ that is an acute angle, a perpendicular angle, or an obtuse angle.

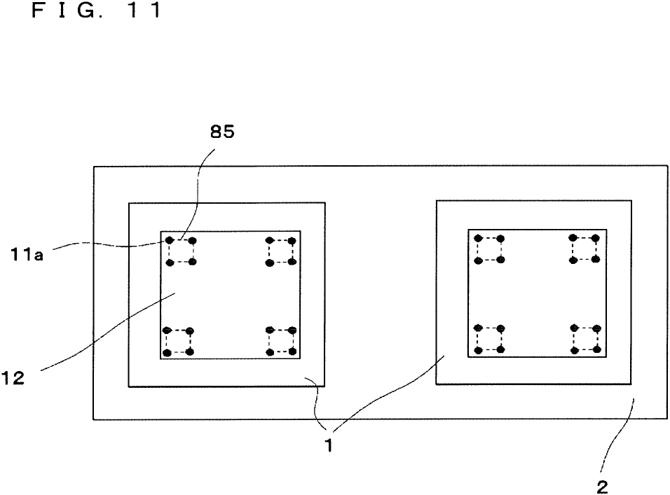

As illustrated in FIG. 10C, a plurality of support wires 11 may be provided, and the distal end portions 11b of the plurality of support wires 11 may be joined discontinuously between the plurality of support wires 11. That is, a plurality of support wires 11 each having one vertex portion 11a may be provided. A distance between the distal end portions 11b of the plurality of support wires 11 is determined in consideration of prevention of tool interference or interference resulting from a squashing width during wire bonding. The plurality of support wires 11 may be provided in parallel to each other or may be provided at an angle to each other. The plurality of support wires 11 may be joined discontinuously and provided so that a polygonal shape is formed when the distal end portions 11b are connected by the virtual line 85. For example, as illustrated in FIG. 10D, the plurality of support wires 11 may be provided discontinuously so that a quadrangular shape is formed when the distal end portions 11b are connected by the virtual line. Furthermore, the support wires 11 may be provided so that a polygon is formed at each of the four corners of the semiconductor element 1 when the vertex portions 11a are connected by the virtual line. For example, as illustrated in FIG. 11, the support wires 11 are provided so that a quadrangular shape is formed at each of the four corners of the semiconductor element when the vertex portions 11a of the support wires 11 are connected by the virtual line 85. Note that it is more preferable that the quadrangular shape is formed at four corners on the active region of the semiconductor element 1.

As described above, according to the semiconductor device 50 of the first preferred embodiment, the electrode plate 7 on the semiconductor element 1 is supported by the plurality of support wires 11, and thereby inclination of the electrode plate 7 can be suppressed.

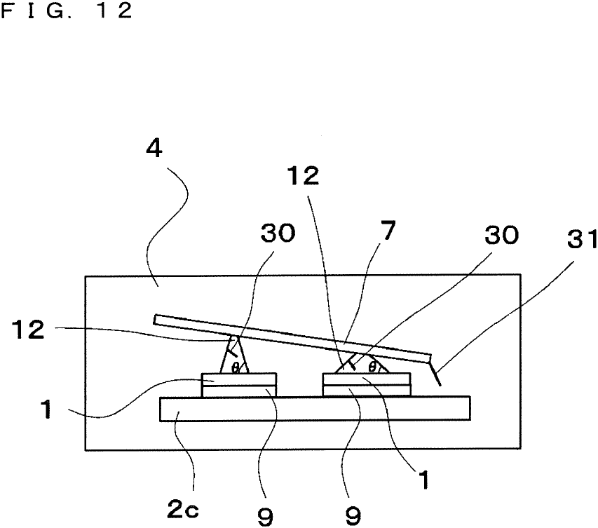

Effects of the semiconductor device 50 configured as described above will be described in comparison with a comparative example. First, FIG. 12 illustrates a schematic view of a case where the electrode plate 7 is inclined as a comparative example. Inclination of the electrode plate 7 may undesirably affect peripheral members such as the second joining material 12 and the sealing material 4. For example, in a case where the electrode plate 7 is inclined, the distance between the semiconductor element 1 and the electrode plate 7 is not constant, and therefore there is a possibility that a crack 30 occurs in a fillet shape of the second joining material 12. The crack 30 of the fillet shape on the semiconductor element 1 causes a decrease in heat radiation and current density, and there arises a difference in heat radiation and current density between the semiconductor elements 1 depending on the presence or absence of the crack 30 of the fillet shape. Note that, although a case where a difference occurs between the plurality of semiconductor elements 1 is described in FIG. 12, the same applies to one semiconductor element 1. For example, in a case where a plurality of second joining materials 12 are provided on one semiconductor element 1, there arises a difference in heat radiation and current density between portions on the same semiconductor element 1 depending on the presence or absence of the crack 30 of the fillet shape in the plurality of second joining materials 12. Note that stress applied to the semiconductor element 1 increases as an angle θ of the fillet shape of the second joining material 12 with respect to the front surface of the semiconductor element 1 increases. Therefore, for example, as illustrated in FIG. 12, in a case where the electrode plate 7 is inclined, the fillet shapes of the second joining materials 12 are different in angle θ with respect to the front surface of the semiconductor element 1, and therefore the stress applied to the semiconductor element 1 becomes uneven. Furthermore, in a case where the sealing material 4 made of an epoxy-based resin is used, stress is applied from the electrode plate 7, and therefore a direction of development of a resin crack 31 from an end portion of the electrode plate 7 toward the sealing material 4 is changed to a direction toward the circuit pattern 2c on which the semiconductor element 1 is disposed depending on whether or not the electrode plate 7 is inclined, and it becomes difficult to ensure insulation performance as designed. In particular, in the semiconductor device 50 in which the electrodes 5 and the electrode plate 7 are integrally formed as illustrated in FIG. 3, one end of the electrode plate 7 is fixed to the case, but the other end of the electrode plate 7 is not fixed to the case, and therefore the electrode plate 7 tends to be inclined due to its own weight.

On the other hand, according to the semiconductor device 50 of the first preferred embodiment, the electrode plate 7 on the semiconductor element 1 is supported by the plurality of support wires 11 to suppress inclination of the electrode plate 7, and thereby influence on a peripheral member around the electrode plate 7 such as the second joining material 12 or the sealing material 4 can be suppressed. For example, occurrence of the crack 30 of the fillet shape on the semiconductor element 1 can be suppressed, and thereby occurrence of a difference in heat radiation and current density between the semiconductor elements 1 or between portions on the same semiconductor element 1 can be suppressed. Furthermore, occurrence of a difference between the fillet shapes in the angle θ between the fillet shape of the second joining material 12 and the front surface of the semiconductor element 1 can be suppressed, and thereby stress on the semiconductor element 1 can be uniformed. Furthermore, in a case where the sealing material 4 made of an epoxy-based resin is used, application of stress from the electrode plate 7 to the sealing material 4 can be suppressed, and therefore it is possible to suppress change of a direction of development of the resin crack 31 from an end portion of the electrode plate 7 toward the sealing material 4 depending on whether or not the electrode plate 7 is inclined. Note that the present disclosure is particularly effective in a semiconductor device in which the electrodes 5 and the electrode plate 7 are integrally formed as illustrated in FIG. 3, and it is possible to suppress inclination of the electrode plate 7 due to its own weight.

### <Modification>

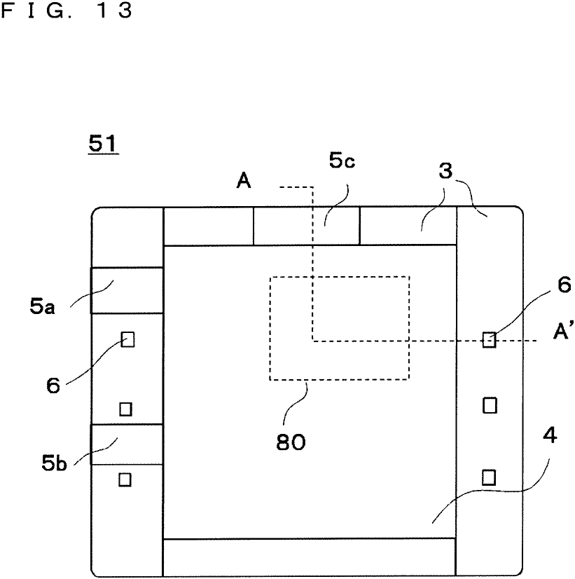

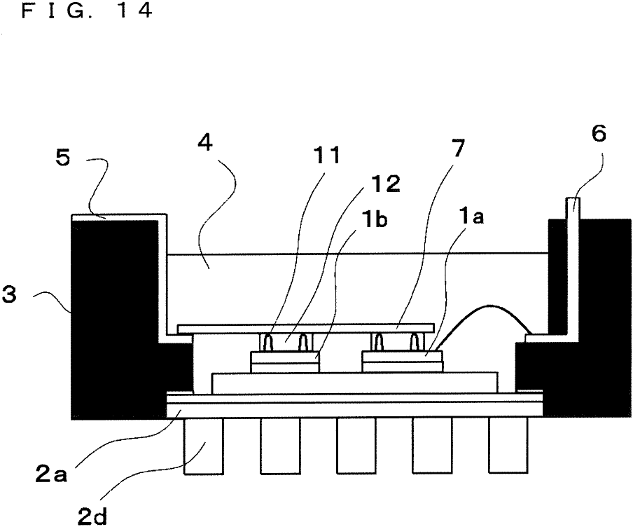

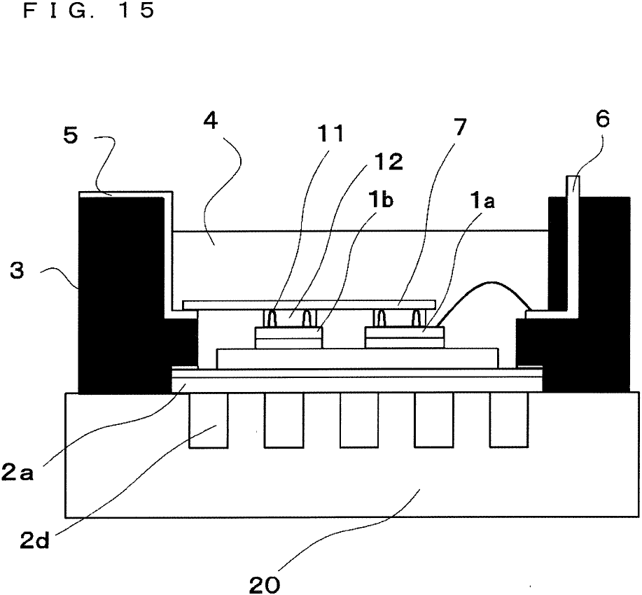

A configuration of a semiconductor device 51 according to a modification of the first preferred embodiment will be described with reference to FIG. 13. FIG. 13 is a plan view illustrating the semiconductor device 51 according to the modification of the first preferred embodiment, and FIG. 14 is a cross-sectional view of the semiconductor device 51 illustrated in FIG. 13 taken along broken line A-A′. FIG. 15 is a cross-sectional view illustrating a configuration in which the semiconductor device 51 according to the modification of the first preferred embodiment is attached to a heat sink 20. Note that, in the modification of the first preferred embodiment, constituent elements identical to those described in the first preferred embodiment are given identical reference signs, and description thereof is omitted.

As illustrated in FIG. 13, in the semiconductor device 51 according to the modification, signal terminals 6 are insert-molded in a case 3. An electrode 5a, an electrode 5b, and an electrode 5c are not provided on parallel sides opposed to each other on a surface of the case 3, and the electrodes 5 and the signal terminals 6 are aligned on one side of the case. Furthermore, as illustrated in FIG. 14, a plurality of pin fins 2d are provided on a lower surface of a metal plate 2a. Each of the pin fins 2d has a cylindrical or prismatic pin shape, and the pin fins 2d improve heat radiation. Note that the pin fins 2d may be integrally molded with the metal plate 2a or the pin fins 2d may be provided as separate members on the metal plate 2a. As illustrated in FIG. 15, the semiconductor device 51 including the pin fins 2d is fixed to the heat sink 20 and cooled. Note that a through hole may be formed in the case 3, the electrode 5, or the like so that a bolt to be screwed can be inserted therethrough in order to fix the semiconductor device including the pin fins 2d to the heat sink 20. In the semiconductor device according to the modification, a cooling method using the heat sink 20 may be a water cooling method using a water cooling jacket instead of an air cooling method. That is, in the semiconductor device according to the modification, a water cooling jacket through which water or the like passes is used as the heat sink 20 to cool the semiconductor device. Even with this configuration, an electrode plate 7 on a semiconductor element 1 is supported by a plurality of support wires 11, and thereby inclination of the electrode plate 7 can be suppressed.

Although other embodiments will be described below, repeated description of effects and the like similar to those of the first preferred embodiment will be omitted.

### Second Preferred Embodiment

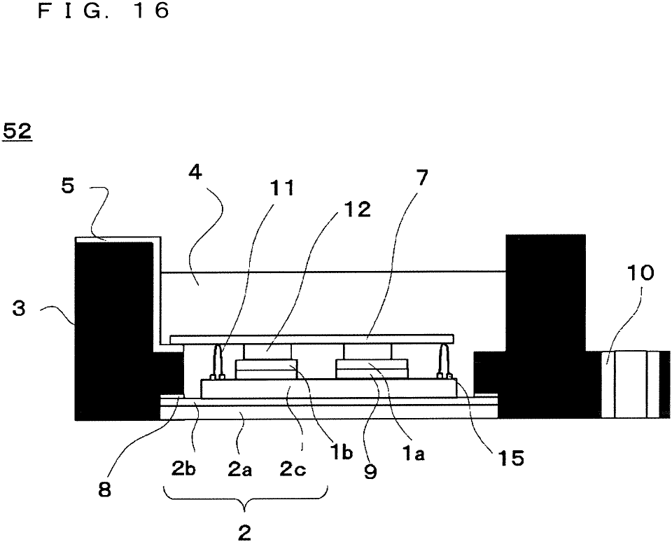

A semiconductor device 52 according to a second preferred embodiment will be described below. FIG. 16 is a cross-sectional view illustrating the semiconductor device 52 according to the second preferred embodiment. In the following description, members such as signal terminals 6 and a conductive wire 13 are omitted for convenience of description. The semiconductor device 52 of the second preferred embodiment is different from the semiconductor device of the first preferred embodiment in that support wires 11 are provided between a front surface of a circuit pattern 2c and a lower surface of an electrode plate 7. A method for producing the semiconductor device 52 is different from the method for producing the semiconductor device according to the first preferred embodiment in that a plurality of support wires 11 are provided on the front surface of the circuit pattern 2c in a support wire installing step.

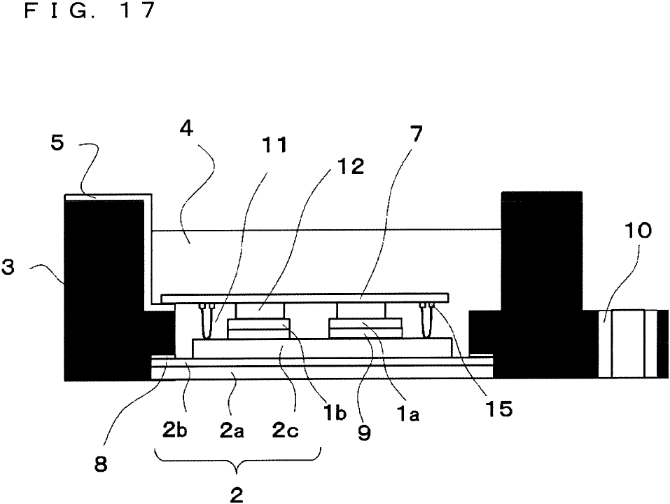

According to the semiconductor device 52 of the second preferred embodiment, the support wires 11 are provided not on the front surface of the semiconductor element 1 but between the front surface of the circuit pattern 2c and the lower surface of the electrode plate 7, and thereby it is possible to suppress damage caused by wire bonding on the semiconductor element 1 when the support wires 11 are attached. Furthermore, the support wires 11 are provided between the front surface of the circuit pattern 2c and the lower surface of the electrode plate 7 with an insulating material 15 interposed therebetween. The insulating material 15 is, for example, polyimide. In a case where the support wires 11 are provided on the circuit pattern 2c, more power can be applied during wire bonding unlike a case where the support wires 11 are provided on the semiconductor element 1, and therefore the support wires 11 can be wire-bonded even in a region where the insulating material 15 covers the circuit pattern 2c. Note that the support wires 11 may be wire-bonded after the insulating material 15 is provided on the support wires 11 themselves or the support wires 11 may be wire-bonded after the insulating material 15 is provided at positions on the circuit pattern 2c or the electrode plate 7 that make contact with distal end portions 11b or vertex portions 11a of the support wires 11. By providing the insulating material 15 at the distal end portions 11b or the vertex portions 11a of the support wires 11, it is possible to prevent conduction between an emitter electrode and a collector electrode of the semiconductor element 1. Although the distal end portions 11b are joined to the circuit pattern 2c with the insulating material 15 interposed therebetween, and the vertex portions 11a make contact with the electrode plate 7 as illustrated in FIG. 16, the distal end portions 11b may be joined to the electrode plate 7 with the insulating material 15 interposed therebetween, and the vertex portions 11a may be provided in contact with the circuit pattern 2c. For example, FIG. 17 illustrates, as a modification of FIG. 16, a modification of the semiconductor device 52 in which the distal end portion 11b is joined to the electrode plate 7 and the vertex portion 11a comes into contact with the circuit pattern 2c. As illustrated in FIG. 17, the distal end portion 11b is joined to the electrode plate 7, and the vertex portion 11a comes into contact with the circuit pattern 2c, and thereby the electrode plate 7 can be supported so that inclination of the electrode plate 7 is suppressed. Furthermore, the semiconductor device 52 according to the second preferred embodiment is an effective embodiment for a case where a chip size is small and it is difficult to provide the support wires 11. For example, in a case where an area on the chip is 10 mm² or less and a wire diameter of the support wires 11 is 100 µm or more, inclination of the support wires 11 can be suppressed without providing the support wires 11 on the chip by employing the configuration of the semiconductor device 52 of the second preferred embodiment.

### Third Preferred Embodiment

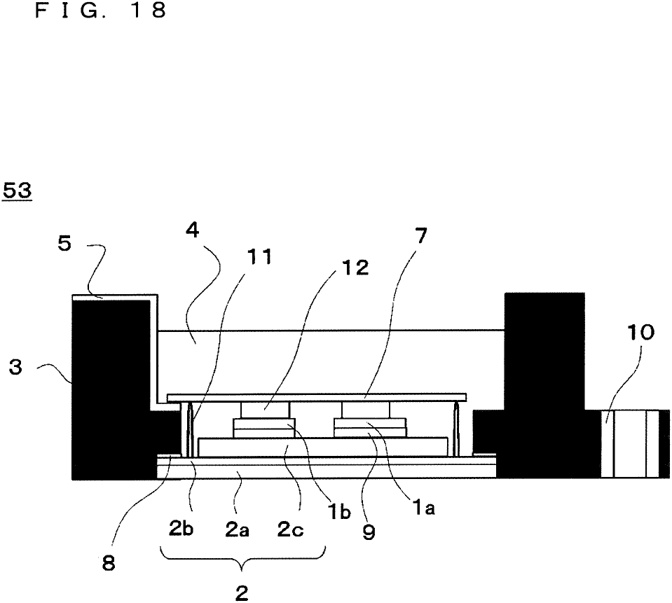

A semiconductor device 53 according to a third preferred embodiment will be described below. FIG. 18 is a cross-sectional view illustrating the semiconductor device 53 according to the third preferred embodiment. In the following description, members such as signal terminals 6 and a conductive wire 13 are omitted for convenience of description. The semiconductor device 53 of the third preferred embodiment is different from the semiconductor devices of the first and second preferred embodiments in that support wires 11 are provided between a front surface of an insulating member 2b and a lower surface of an electrode plate 7. A method for producing the semiconductor device 53 is different from the methods for producing the semiconductor device according to the first and second preferred embodiments in that a plurality of support wires 11 are provided on the front surface of the insulating member 2b in a support wire installing step.

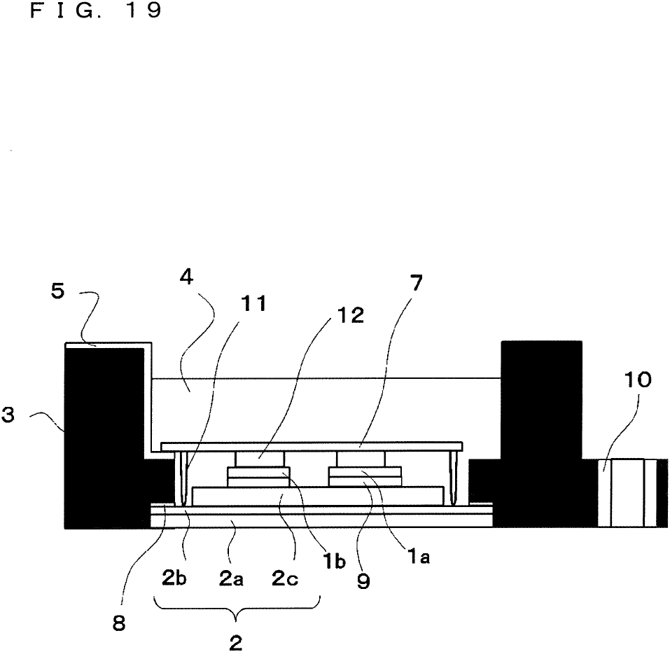

According to the semiconductor device 53 of the third preferred embodiment, the support wires 11 are provided not on the front surface of the semiconductor element 1 but between the front surface of the insulating member 2b and the lower surface of the electrode plate 7, and thereby no stress is applied from a wire bonding tool onto the semiconductor element 1 when the support wires 11 are attached. Furthermore, in the third preferred embodiment, since the support wires 11 are provided between the front surface of the insulating member 2b and the lower surface of the electrode plate 7, it is also possible to prevent conduction between an emitter electrode and a collector electrode of the semiconductor element 1 without providing an insulating material 15 unlike the second preferred embodiment. Although distal end portions 11b are joined to the insulating member 2b, and vertex portions 11a make contact with the electrode plate 7 as illustrated in FIG. 18, the distal end portions 11b may be joined to the electrode plate 7, and the vertex portions 11a may be provided in contact with the insulating member 2b. For example, FIG. 19 illustrates, as a modification of FIG. 18, a modification of the semiconductor device 53 in which the distal end portion 11b is joined to the electrode plate 7 and the vertex portion 11a comes into contact with the insulating member 2b. As illustrated in FIG. 19, the distal end portion 11b is joined to the electrode plate 7, and the vertex portion 11a comes into contact with the insulating member 2b, and thereby the electrode plate 7 can be supported so that inclination of the electrode plate 7 is suppressed. Furthermore, the semiconductor device 53 according to the third preferred embodiment is an effective embodiment for a case where a chip size is small and it is difficult to provide the support wires 11. For example, in a case where an area on the chip is 10 mm² or less and a wire diameter of the support wires 11 is 100 µm or more, inclination of the support wires 11 can be suppressed without providing the support wires 11 on the chip by employing the configuration of the semiconductor device 53 of the third preferred embodiment.

### Fourth Preferred Embodiment

The present preferred embodiment is an embodiment in which the semiconductor device according to the first to third preferred embodiments is applied to a power conversion apparatus. A case where the present disclosure is applied to a three-phase inverter will be described below as the fourth preferred embodiment although the present disclosure is not limited to a specific power conversion apparatus.

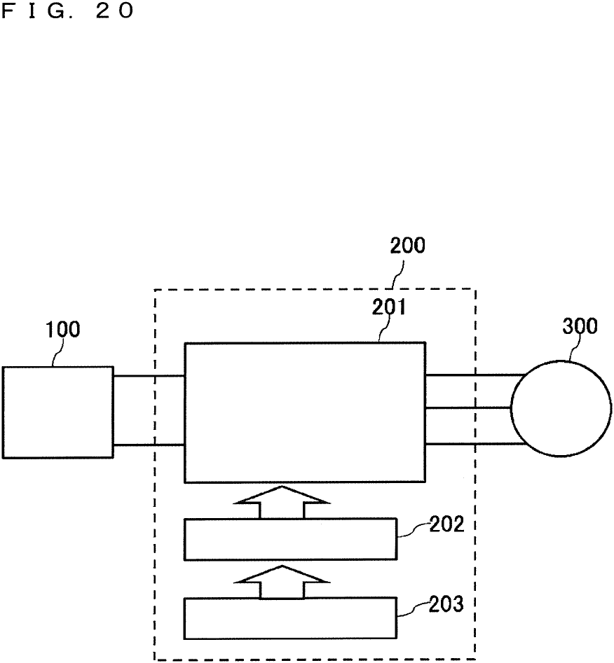

FIG. 20 is a block diagram illustrating a configuration of a power conversion system to which the power conversion apparatus according to the present preferred embodiment is applied.

The power conversion system illustrated in FIG. 20 includes a power supply 100, a power conversion apparatus 200, and a load 300. The power supply 100 is a DC power supply, and supplies DC power to the power conversion apparatus 200. The power supply 100 can be any of various power supplies, and may be, for example, a DC system, a solar cell, or a rechargeable battery or may be a rectifier circuit or an AC/DC converter connected to an AC system. Alternatively, the power supply 100 may be a DC/DC converter that converts DC power output from a DC system into predetermined power.

The power conversion apparatus 200 is a three-phase inverter connected between the power supply 100 and the load 300, converts DC power supplied from the power supply 100 into AC power, and supplies the AC power to the load 300. As illustrated in FIG. 20, the power conversion apparatus 200 includes a main conversion circuit 201 that converts DC power into AC power and outputs the AC power, a drive circuit 202 that outputs a drive signal for driving each switching element of the main conversion circuit 201, and a control circuit 203 that outputs a control signal for controlling the drive circuit 202 to the drive circuit 202.

The load 300 is a three-phase electric motor driven by the AC power supplied from the power conversion apparatus 200. The load 300 is not limited to a specific application and is an electric motor mounted on various electric devices, and is, for example, used as an electric motor for a hybrid vehicle, an electric vehicle, a railway vehicle, an elevator, or an air conditioner.

Details of the power conversion apparatus 200 will be described below. The main conversion circuit 201 includes a switching element and a freewheeling diode (not illustrated), converts DC power supplied from the power supply 100 into AC power by switching of the switching element, and supplies the AC power to the load 300. Although various configurations are available as a specific circuit configuration of the main conversion circuit 201, the main conversion circuit 201 according to the present preferred embodiment is a two-level three-phase full bridge circuit, and can include six switching elements and six freewheeling diodes connected in anti-parallel to the respective switching elements. Any of the semiconductor devices according to the first to third preferred embodiments is applied as each switching element of the main conversion circuit 201. Each two of the six switching elements are connected in series to constitute upper and lower arms, and the upper and lower arms constitute phases (a U-phase, a V-phase, a W-phase) of the full bridge circuit. Output terminals of the upper and lower arms, that is, three output terminals of the main conversion circuit 201 are connected to the load 300.

The drive circuit 202 generates a drive signal for driving the switching elements of the main conversion circuit 201, and supplies the drive signal to control electrodes of the switching elements of the main conversion circuit 201. Specifically, the drive circuit 202 outputs a drive signal for turning on the switching elements and a drive signal for turning off the switching elements to the control electrodes of the switching elements in accordance with a control signal from the control circuit 203, which will be described later. In a case where the switching elements are maintained in an ON state, the drive signal is a voltage signal (ON signal) equal to or higher than a threshold voltage of the switching elements, and in a case where the switching elements are maintained in an OFF state, the drive signal is a voltage signal (OFF signal) equal to or lower than the threshold voltage of the switching elements.

The control circuit 203 controls the switching elements of the main conversion circuit 201 so that desired power is supplied to the load 300. Specifically, the control circuit 203 calculates a time (ON time) for which each switching element of the main conversion circuit 201 is to be in an ON state based on the power to be supplied to the load 300. For example, the control circuit 203 can control the main conversion circuit 201 by PWM control for modulating the ON time of the switching elements in accordance with a voltage to be output. Then, the control circuit 203 outputs a control command (control signal) to the drive circuit 202 so that an ON signal is output to a switching element to be in an ON state at each time point and an OFF signal is output to a switching element to be in an OFF state at each time point. The drive circuit 202 outputs an ON signal or an OFF signal as a drive signal to the control electrode of each switching element in accordance with the control signal.

In the power conversion apparatus according to the present preferred embodiment, any of the semiconductor devices according to the first to third preferred embodiments is applied as the switching element of the main conversion circuit 201, an electrode plate 7 on a semiconductor element 1 is supported by a plurality of support wires 11, and thereby inclination of the electrode plate 7 can be suppressed, and reliability can be improved.

Although an example in which the present disclosure is applied to the two-level three-phase inverter has been described in the present preferred embodiment, the present disclosure is not limited to this and can be applied to various power conversion apparatuses. Although the power conversion apparatus is a two-level power conversion apparatus in the present preferred embodiment, the power conversion apparatus may be a three-level or multi-level power conversion apparatus or the present disclosure may be applied to a single-phase inverter in a case where power is supplied to a single-phase load. In a case where power is supplied to a DC load or the like, the present disclosure can be applied to a DC/DC converter or an AC/DC converter.

Furthermore, the power conversion apparatus to which the present disclosure is applied is not limited to the case where the load is an electric motor, and can be used as, for example, a power supply device of an electric discharge machine, a laser beam machine, an induction heating cooker, or a contactless power feeding system, and can also be used as a power conditioner of a solar power generation system, a power storage system, or the like.

Although the switching element and the diode element are formed of silicon in the above preferred embodiment, the switching element and the diode element may be formed of a wide band gap semiconductor having a band gap larger than that of silicon. Examples of the wide band gap semiconductor include silicon carbide, a gallium nitride-based material, and diamond.

Since the switching element and the diode element formed of such a wide band gap semiconductor have high withstand voltage and high allowable current density, it is possible to downsize the switching element and the diode element. By using these downsized switching element and diode element, it is possible to downsize a semiconductor module incorporating these elements.

In addition, since heat resistance is also high, a heat radiation fin of the heat sink 20 can be downsized, and a water cooling portion can be changed to an air cooling portion, and therefore the semiconductor device can be further downsized.

Furthermore, since a power loss is low, efficiency of the switching element and the diode element can be made high, and as a result, efficiency of the semiconductor device can be made high.

Both the switching element and the diode element are preferably made of a wide band gap semiconductor, but either one of the switching element and the diode element may be made of a wide band gap semiconductor, and the effects described in the present preferred embodiment can be obtained.

Although some preferred embodiments of the present disclosure have been described, these preferred embodiments have been presented by way of example. Various omissions, substitutions, and changes can be made without departing from the gist of the present disclosure. Further, the preferred embodiments can be combined.

While the disclosure has been shown and described in detail, the foregoing description is in all aspects illustrative and not restrictive. It is therefore understood that numerous modifications and variations can be devised.

What is claimed is:

1. A semiconductor device, comprising:
an insulating substrate;
a semiconductor element joined onto the insulating substrate with a first joining material interposed therebetween;
an electrode plate provided above the semiconductor element;
a plurality of support wires that are provided between the semiconductor element and the electrode plate in contact with the semiconductor element and the electrode plate; and
a second joining material that is provided on the semiconductor element and joins the semiconductor element and the electrode plate.

2. The semiconductor device according to claim 1, wherein
each of the support wires has a distal end portion at both ends thereof and a vertex portion that includes a vertex of the support wire and is provided between the distal end portions of the support wire,
the distal end portions are in contact with the semiconductor element, and
the vertex portion is in contact with the electrode plate.

3. The semiconductor device according to claim 1, wherein
each of the support wires has a distal end portion at both ends thereof and a vertex portion that includes a vertex of the support wire and is provided between the distal end portions of the support wire,
the vertex portion is in contact with the semiconductor element, and
the distal end portions are in contact with the electrode plate.

4. A semiconductor device, comprising:
a circuit pattern;
an insulating member provided below the circuit pattern;
a semiconductor element joined onto the circuit pattern with a first joining material interposed therebetween;
an electrode plate provided above the circuit pattern and the semiconductor element;
a plurality of support wires that are provided between the circuit pattern and the electrode plate in contact with the circuit pattern and the electrode plate; and
a second joining material that is provided on the semiconductor element and joins the semiconductor element and the electrode plate.

5. The semiconductor device according to claim 4, wherein
each of the support wires has a distal end portion at both ends thereof and a vertex portion that includes a vertex of the support wire and is provided between the distal end portions of the support wire,
the distal end portions are in contact with the circuit pattern, and
the vertex portion is in contact with the electrode plate.

6. The semiconductor device according to claim 4, wherein
each of the support wires has a distal end portion at both ends thereof and a vertex portion that includes a vertex of the support wire and is provided between the distal end portions of the support wire,
the vertex portion is in contact with the circuit pattern, and
the distal end portions are in contact with the electrode plate.

7. The semiconductor device according to claim 4, wherein the circuit pattern or the electrode plate has an insulating material on a surface thereof, and the insulating material is interposed between the support wires and the circuit pattern or the electrode plate.

8. A semiconductor device, comprising:
a circuit pattern;
an insulating member provided below the circuit pattern;
a semiconductor element joined onto the circuit pattern with a first joining material interposed therebetween;
an electrode plate provided above the insulating member and the semiconductor element;
a plurality of support wires that are provided between the insulating member and the electrode plate in contact with the insulating member and the electrode plate; and
a second joining material that is provided on the semiconductor element and joins the semiconductor element and the electrode plate.

9. The semiconductor device according to claim 8, wherein
each of the support wires has a distal end portion at both ends thereof and a vertex portion that includes a vertex of the support wire and is provided between the distal end portions of the support wire,
the distal end portions are in contact with the insulating member, and
the vertex portion is in contact with the electrode plate.

10. The semiconductor device according to claim 8, wherein
each of the support wires has a distal end portion at both ends thereof and a vertex portion that includes a vertex of the support wire and is provided between the distal end portions of the support wire,
the vertex portion is in contact with the insulating member, and
the distal end portions are in contact with the electrode plate.

11. The semiconductor device according to claim 1, wherein three or more support wires are provided on the semiconductor element.

12. The semiconductor device according to claim 1, wherein the support wires are provided at four corners in plan view on the semiconductor element.

13. The semiconductor device according to claim 1, wherein each of the support wires has a single vertex portion.

14. The semiconductor device according to claim 1, wherein each of the support wires has a plurality of vertex portions.

15. The semiconductor device according to claim 1, wherein a distance between the distal end portions is 0.5 mm or more.

16. The semiconductor device according to claim 1, wherein each of the support wires is at least partially embedded in the second joining material.

17. The semiconductor device according to claim 1, wherein the insulating substrate or the insulating member has a heat radiation member on a lower surface thereof.

18. A power conversion apparatus, comprising:
a main conversion circuit that includes the semiconductor device according to claim 1 and converts input power and outputs the converted power;
a drive circuit that outputs a drive signal for driving the semiconductor device to the semiconductor device; and
a control circuit that outputs a control signal for controlling the drive circuit to the drive circuit.

19. A method for producing a semiconductor device, the method comprising:
a die bonding step of joining a semiconductor element onto an insulating substrate with a first joining material interposed therebetween;
a support wire installing step of providing a plurality of support wires on the semiconductor element; and
an electrode plate attaching step of placing an electrode plate on the plurality of support wires so that the plurality of support wires support the electrode plate, and joining the semiconductor element and the electrode plate with a second joining material interposed therebetween.
